(19) United States
(12) Patent Application Publication
(10) Pub. No.: US 2024/0405176 A1
(43) Pub. Date: Dec. 5, 2024

(54) SINTERED COMPACT SUBSTRATE, LIGHT-EMITTING DEVICE, AND METHODS FOR MANUFACTURING SINTERED COMPACT SUBSTRATE AND LIGHT-EMITTING DEVICE

(71) Applicant: NICHIA CORPORATION, Anan-shi (JP)

(72) Inventors: Atsushi HOSOKAWA, Tokushima-shi (JP); Masaaki KATSUMATA, Anan-shi (JP)

(73) Assignee: NICHIA CORPORATION, Anan-shi (JP)

(21) Appl. No.: 18/671,989

(22) Filed: May 23, 2024

(30) Foreign Application Priority Data
May 31, 2023 (JP) 2023-090220

(51) Int. Cl. H01L 33/62; H01L 33/64

(52) U.S. Cl. CPC H01L 33/62; H01L 33/641; H01L 2933/0066; H01L 2933/0075

(57) ABSTRACT

A method includes providing a ceramic substrate having a first arrangement portion recessed from a first planar portion; disposing a first conductive paste containing a first metal powder in the first arrangement portion; obtaining a first conductor by firing the first conductive paste; forming first recessed portions on a surface of the first conductor disposed in the first arrangement portion by polishing the first conductor and the ceramic substrate so that the first conductor and the first surface form a same plane; disposing a second conductive paste containing a second metal powder and a second organic resin binder in the first recessed portions; obtaining a second conductor by curing the second conductive paste; polishing the second conductor so that the second conductor and the first conductor form the same plane; and forming a first metal layer on surfaces of the first conductor and the second conductor.

### CROSS-REFERENCE TO RELATED APPLICATIONS

The present application claims priority under 35 U.S.C. § 119 to Japanese Patent Application No. 2023-090220, filed May 31, 2023, the contents of which is hereby incorporated by reference in its entirety.

### BACKGROUND

### 1. Technical Field

The present disclosure relates to a sintered compact substrate, a light-emitting device, and methods for manufacturing the sintered compact substrate and the light-emitting device.

### 2. Description of Related Art

In the related art, a circuit device in which wiring layers are formed on a circuit board and a resin is embedded as an insulating material between the wiring layers has been known (for example, see Japanese Patent Publication No. 2005-347357). A lead frame substrate for high heat dissipation in which a heat conductive substrate includes a metal plate, a heat conductive insulating layer, or a low elastic insulating layer, and lead frames and a space between the lead frames is protected by a smoothing resin has been known (for example, see Japanese Patent Publication No. 2014-99574).

### SUMMARY

Embodiments of the present disclosure can provide a sintered compact substrate in which a metal layer such as a wiring is planarized and which has excellent thermal conductivity, and a method for manufacturing the sintered compact substrate.

A first aspect of the present disclosure is a method for manufacturing a sintered compact substrate including providing a ceramic substrate having a first surface and a second surface opposite to the first surface and including a first arrangement portion recessed from a first planar portion of the first surface, disposing a first conductive paste containing a first metal powder in the first arrangement portion, obtaining a first conductor by firing the first conductive paste, forming a plurality of first recessed portions on a surface of the first conductor disposed in the first arrangement portion by polishing or grinding at least one of the first conductor or the ceramic substrate so that the first conductor and the first surface form the same plane, disposing a second conductive paste containing a second metal powder and a second organic resin binder in the plurality of first recessed portions, obtaining a second conductor by curing the second conductive paste, polishing or grinding the second conductor so that the second conductor and the first conductor form the same plane, and forming a first metal layer on surfaces of the first conductor and the polished or ground second conductor.

A second aspect of the present disclosure is a sintered compact substrate including a ceramic substrate having a first surface and a second surface opposite to the first surface and including a first arrangement portion recessed from a first planar portion of the first surface, a first conductor disposed in the first arrangement portion and including a plurality of first recessed portions on a surface of the first conductor, a second conductor disposed in the first recessed portion, and a first metal layer disposed on surfaces of the first conductor and the second conductor, in which the surface of the first conductor, the surface of the second conductor, and the first surface are flush with each other.

A third aspect of the present disclosure is a method for manufacturing a light-emitting device including providing a sintered compact substrate obtained by the method for manufacturing the sintered compact substrate, and disposing a light-emitting element including an element electrode on the sintered compact substrate, in which in the step of disposing the light-emitting element, the element electrode and the first metal layer are electrically connected to each other.

A fourth aspect of the present disclosure is a light-emitting device including the sintered compact substrate, and a light-emitting element disposed on the sintered compact substrate and including an element electrode, in which the element electrode and the first metal layer are electrically connected to each other.

An aspect of the present disclosure can provide a sintered compact substrate in which a metal layer such as a wiring is planarized and which has excellent thermal conductivity, and a method for manufacturing the sintered compact substrate.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1A is a schematic plan view illustrating a sintered compact substrate according to a first embodiment.

FIG. 1B is a schematic cross-sectional view illustrating a cross section taken along line IB-IB in FIG. 1A.

FIG. 2A is a schematic cross-sectional view illustrating a provided ceramic substrate in a method for manufacturing the sintered compact substrate according to the first embodiment.

FIG. 2B is a schematic cross-sectional view illustrating a state in which a first conductive paste is disposed in the method for manufacturing the sintered compact substrate according to the first embodiment.

FIG. 2C is a schematic cross-sectional view illustrating a state in which a first conductor is formed in the method for manufacturing the sintered compact substrate according to the first embodiment.

FIG. 2D is a schematic cross-sectional view illustrating a state in which at least one of the first conductor or the ceramic substrate is polished or ground in the method for manufacturing the sintered compact substrate according to the first embodiment.

FIG. 2E is a schematic cross-sectional view illustrating a state in which a second conductive paste is disposed in the method for manufacturing the sintered compact substrate according to the first embodiment.

FIG. 2F is a schematic cross-sectional view illustrating a state in which a second conductor is formed in the method for manufacturing the sintered compact substrate according to the first embodiment.

FIG. 2G is a schematic cross-sectional view illustrating a state in which the second conductor is polished or ground in the method for manufacturing the sintered compact substrate according to the first embodiment.

FIG. 2H is a schematic cross-sectional view illustrating a state in which a first metal layer is formed in the method for manufacturing the sintered compact substrate according to the first embodiment.

FIG. 3A is a schematic cross-sectional view illustrating a provided ceramic substrate in a method for manufacturing a sintered compact substrate according to a second embodiment.

FIG. 3B is a schematic cross-sectional view illustrating a state in which a third conductive paste is disposed in the method for manufacturing the sintered compact substrate according to the second embodiment.

FIG. 3C is a schematic cross-sectional view illustrating a state in which a third conductor is formed in the method for manufacturing the sintered compact substrate according to the second embodiment.

FIG. 3D is a schematic cross-sectional view illustrating a state in which at least one of the third conductor or the ceramic substrate is polished or ground in the method for manufacturing the sintered compact substrate according to the second embodiment.

FIG. 3E is a schematic cross-sectional view illustrating a state in which a fourth conductive paste is disposed in the method for manufacturing the sintered compact substrate according to the second embodiment.

FIG. 3F is a schematic cross-sectional view illustrating a state in which a fourth conductor is formed in the method for manufacturing the sintered compact substrate according to the second embodiment.

FIG. 3G is a schematic cross-sectional view illustrating a state in which the fourth conductor is polished or ground in the method for manufacturing the sintered compact substrate according to the second embodiment.

FIG. 3H is a schematic cross-sectional view illustrating a state in which a second metal layer is formed in the method for manufacturing the sintered compact substrate according to the second embodiment.

FIG. 4A is a schematic plan view illustrating a sintered compact substrate according to a third embodiment.

FIG. 4B is a schematic cross-sectional view illustrating a cross section taken along line IVB-IVB in FIG. 4A.

FIG. 5A is a schematic cross-sectional view illustrating a provided ceramic substrate in a method for manufacturing a sintered compact substrate according to the third embodiment.

FIG. 5B is a schematic cross-sectional view illustrating a state in which a fifth conductor is formed in the method for manufacturing the sintered compact substrate according to the third embodiment.

FIG. 5C is a schematic cross-sectional view illustrating a state in which at least one of the fifth conductor or the ceramic substrate is polished or ground in the method for manufacturing the sintered compact substrate according to the third embodiment.

FIG. 5D is a schematic cross-sectional view illustrating a state in which a second conductor and a fourth conductor are formed and are polished or ground in the method for manufacturing the sintered compact substrate according to the third embodiment.

FIG. 5E is a schematic cross-sectional view illustrating a state in which a first metal layer and a second metal layer are formed in the method for manufacturing the sintered compact substrate according to the third embodiment.

FIG. 6A is a schematic plan view illustrating a light-emitting device according to an embodiment.

FIG. 6B is a schematic cross-sectional view illustrating a cross section taken along line VIB-VIB in FIG. 6A.

FIG. 7A is a schematic plan view illustrating a light-emitting element of a light-emitting device according to an embodiment.

FIG. 7B is a schematic bottom view illustrating a light-emitting element of a light-emitting device according to an embodiment.

FIG. 8 is a schematic plan view illustrating an assembly of light-emitting devices before singulation in a method for manufacturing a light-emitting device according to an embodiment.

FIG. 9A is a schematic cross-sectional view illustrating an assembly of provided sintered compact substrates in a method for manufacturing a light-emitting device according to an embodiment.

FIG. 9B is a schematic cross-sectional view illustrating a state in which conductive members are disposed in a method for manufacturing a light-emitting device according to an embodiment.

FIG. 9C is a schematic cross-sectional view illustrating a state in which a light-emitting element is disposed in a method for manufacturing a light-emitting device according to an embodiment.

FIG. 9D is a schematic cross-sectional view illustrating a state in which a covering member is disposed in a method for manufacturing a light-emitting device according to an embodiment.

FIG. 9E is a schematic cross-sectional view illustrating a light-emitting device obtained by singulation in a method for manufacturing a light-emitting device according to an embodiment.

### DETAILED DESCRIPTION

### Description of Embodiments

Embodiments according to the present disclosure will be described below with reference to the drawings. However, the embodiments described below are merely intended to embody the technical concept according to the present disclosure, and the invention is not limited to the following description unless otherwise specified. The content described in one embodiment can also be applied to another embodiment or modification. The drawings schematically illustrate embodiments, and in order to clarify the description, scales, intervals, positional relationships, and the like of the members may be exaggerated, illustration of a part of the members may be omitted, or an end view illustrating only a cut surface may be used as a cross-sectional view. Directions illustrated in the drawings indicate relative positions between constitution components and are not intended to indicate absolute positions. Members having the same names and reference characters, as a rule, represent the same members or members of the same quality, and detailed description thereof is omitted as appropriate. In the embodiments, “covering” includes not only a case of covering by direct contact but also a case of indirectly covering, for example, via another member.

### First Embodiment

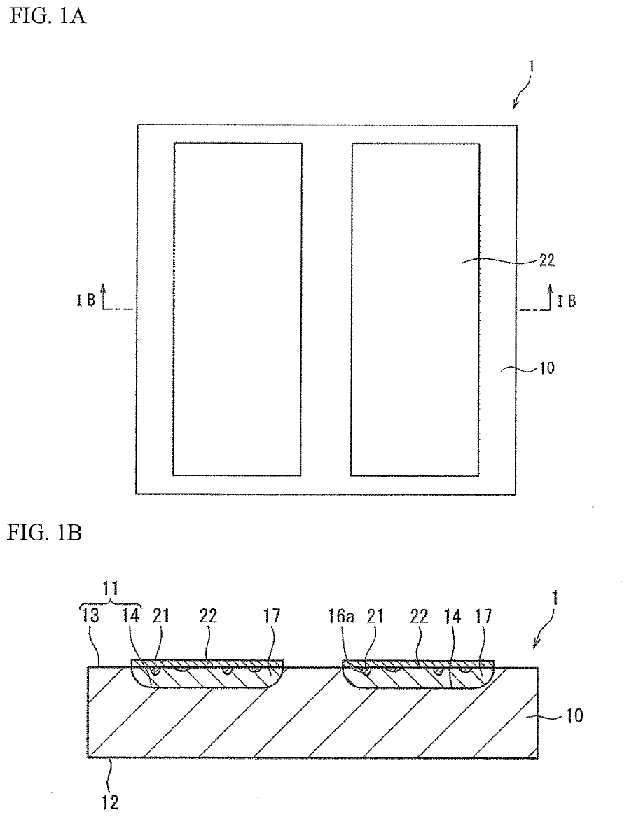

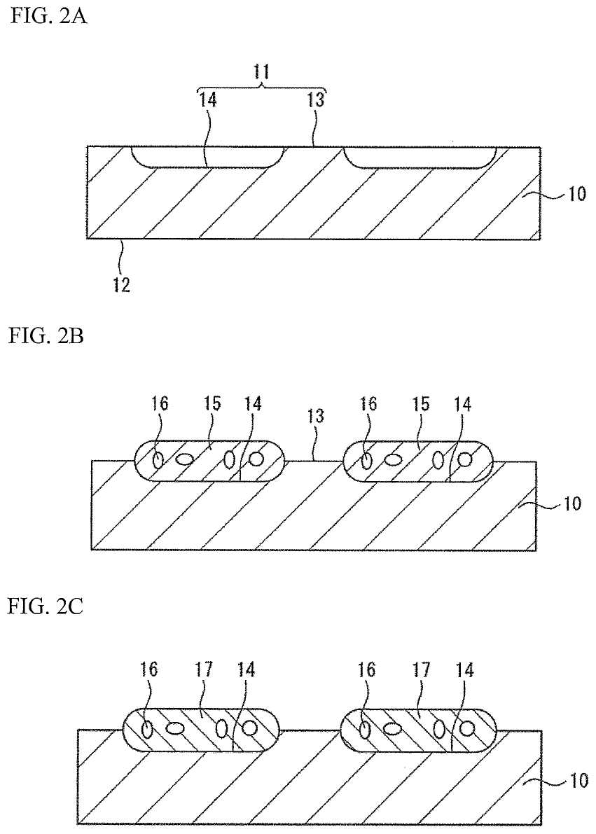

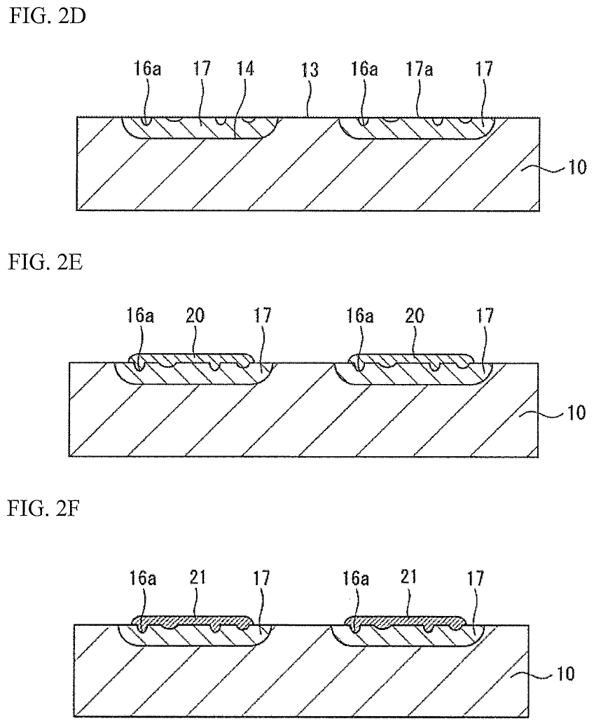

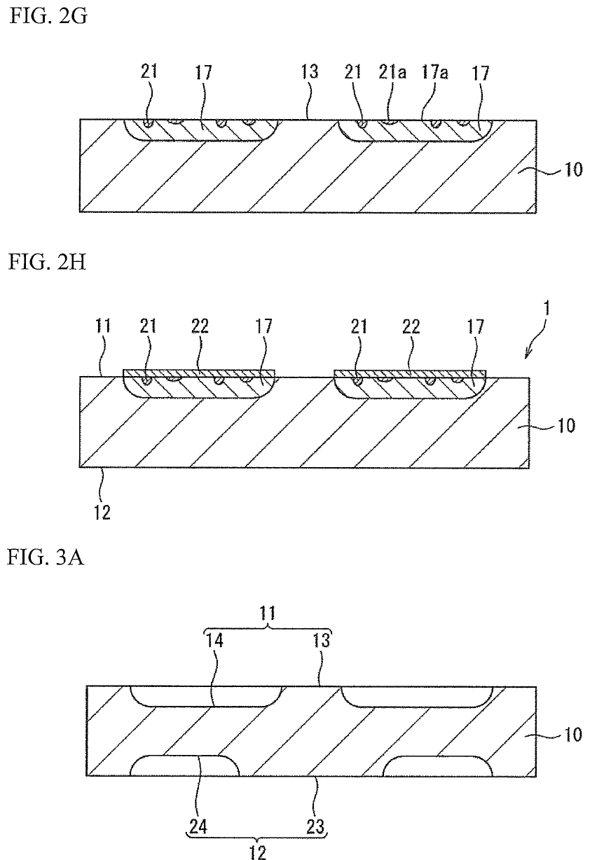

A sintered compact substrate and a method for manufacturing the sintered compact substrate according to a first embodiment are described with reference to FIGS. 1A and 1B and FIGS. 2A to 2H. FIG. 1A is a schematic plan view illustrating a sintered compact substrate 1. FIG. 1B is a schematic cross-sectional view illustrating a cross section taken along line IB-IB in FIG. 1A. FIGS. 2A to 2H are cross-sectional views for illustrating a method for manufacturing the sintered compact substrate 1 illustrated in FIG. 1A.

The sintered compact substrate 1 of the first embodiment according to the present disclosure includes a ceramic substrate 10 having a first surface 11 and a second surface 12 opposite to the first surface 11 and including a first arrangement portion 14 recessed from a first planar portion 13 of the first surface 11; a first conductor 17 disposed in the first arrangement portion 14; a second conductor 21 disposed in a first recessed portion 16a of the first conductor 17; and a first metal layer 22 disposed on surfaces of the first conductor 17 and the second conductor 21, in which the first conductor 17, the second conductor 21, and the first planar portion 13 of the first surface 11 are flush with each other.

A method for manufacturing the sintered compact substrate of the first embodiment according to the present disclosure includes: (a) providing the ceramic substrate 10 having the first surface 11 and the second surface 12 opposite to the first surface 11 and including the first arrangement portion 14 recessed from the first planar portion 13 of the first surface 11; (b) disposing a first conductive paste 15 containing a first metal powder in the first arrangement portion 14; (c) obtaining the first conductor 17 by firing the first conductive paste 15; (d) forming a plurality of first recessed portions 16a on the surface of the first conductor 17 disposed in the first arrangement portion 14 by polishing or grinding at least one of the first conductor 17 or the ceramic substrate 10 so that the first conductor 17 and the first surface 11 form the same plane; (e) disposing a second conductive paste 20 containing a second metal powder and a second organic resin binder in the plurality of first recessed portions 16a; (f) obtaining the second conductor 21 by curing the second conductive paste 20; (g) polishing or grinding the second conductor 21 so that the second conductor 21 and the first conductor 17 form the same plane; and (h) forming the first metal layer 22 on the surfaces of the first conductor 17 and the polished or ground second conductor 21.

The steps are described in detail below.

### (a) Providing Ceramic Substrate

The ceramic substrate 10 is provided (FIG. 2A).

The ceramic substrate 10 is an insulating member serving as a base on which the first conductor 17 is disposed later. The ceramic substrate 10 has the first surface 11 and the second surface 12 opposite to the first surface 11. The first surface 11 includes the first planar portion 13 and the first arrangement portion 14 recessed from the first planar portion 13. The first planar portion 13 is a flat surface and constitutes a part of an outer surface of the sintered compact substrate 1. Although the ceramic substrate 10 having two first arrangement portions 14 corresponding to one sintered compact substrate 1 is illustrated, a ceramic substrate 10 including a plurality of first arrangement portions 14 corresponding to a plurality of sintered compact substrates 1 can be used.

The material of the ceramic substrate 10 is preferably a ceramic having high thermal conductivity from the viewpoint of heat dissipation. For example, the ceramic substrate 10 is preferably made of a nitride ceramic such as silicon nitride, aluminum nitride, or boron nitride, but can be made of an oxide ceramic such as aluminum oxide, silicon oxide, calcium oxide, or magnesium oxide.

The thickness of the ceramic substrate 10 is preferably, for example, in a range from 0.08 mm to 2 mm.

The first arrangement portion 14 has a rectangular shape in plan view, and has a long direction and a short direction. The two first arrangement portions 14 are arranged so that long sides thereof face each other. The first arrangement portion 14 can have round corners in plan view, or the entire end in the long direction of the first arrangement portion 14 can be curved. An inner lateral surface of the first arrangement portion 14 in a plate thickness direction can be a curved surface. In cross-sectional view of the ceramic substrate 10 in the plate thickness direction, surfaces of the first arrangement portion 14 are curved except for a flat surface of a part of a bottom surface of the first arrangement portion 14. The first arrangement portion 14 can have a curved bottom surface that continues from the inner lateral surface. For example, in cross-sectional view of the ceramic substrate 10 in the thickness direction, the shape of the first arrangement portion 14 can be curved.

An inner surface defining the first arrangement portion 14 is preferably roughened. The roughening can reduce peeling of the first conductor 17 disposed in the first arrangement portion 14. An arithmetic mean roughness Ra of the inner surface defining the first arrangement portion 14 can be, for example, in a range from 200 nm to 2 μm, and is preferably in a range from 300 nm to 800 nm. The arithmetic mean roughness Ra can be measured in accordance with JIS B 0601 using a stylus type surface roughness measuring instrument (for example, SE 3500 manufactured by Kosaka Laboratory Ltd.) equipped with a diamond stylus having a tip radius r of curvature of 2 μm.

The ceramic substrate 10 is a fired substrate. When a green sheet before firing is used and the first conductive paste to be described below is disposed on the green sheet, warpage or shrinkage increases, making it difficult to dispose the first arrangement portion with high accuracy. On the other hand, in the present embodiment, since a fired ceramic substrate is used and the first conductive paste is disposed on the ceramic substrate, warpage and shrinkage are significantly reduced, making it possible to dispose the first arrangement portion with high accuracy. The ceramic substrate 10 can be molded by firing a ceramic, or a fired substrate such as a commercially available product can be used. The first arrangement portion 14 in the ceramic substrate 10 can be provided in advance, or can be formed after purchasing a fired substrate such as a commercially available product. Alternatively, a substrate on which the first arrangement portion 14 is formed can be purchased as the ceramic substrate 10.

The first arrangement portion 14 can be formed, for example, by etching, blasting, or laser processing. Thus, the inner lateral surface defining the first arrangement portion 14 can be formed in a curved shape. Only one of etching, blasting, and laser processing can be performed, or two or more of these can be combined. The bottom surface defining the recessed portion of the first arrangement portion 14 in cross-sectional view can partially have a flat portion.

As the etching, wet etching or dry etching can be performed, and the wet etching is preferable. In the wet etching, by performing etching using an acidic or alkaline chemical such as HF, NH₄F, KOH, NaOH, or CsOH, the first arrangement portion 14 having a curved shape can be formed.

In the blasting, abrasive grains are caused to collide with the first surface 11 from a perpendicular direction, so that the ceramic substrate 10 is polished or ground and the curved shape and the roundness of connection portions can be formed.

Before the etching or blasting, a resist having a predetermined pattern can be disposed. For example, the resist is formed as follows.

A dry film is bonded to the first surface 11 of the ceramic substrate. The dry film is a sheet-like photoresist. For example, use the dry film in which the exposed region is cured.

Subsequently, the dry film is exposed and developed. Before the exposure, a mask is attached to the dry film in an overlapping manner. The mask has a light-shielding pattern in a region where the first arrangement portion 14 is to be formed. Subsequently, light is emitted to perform exposure. The light is, for example, ultraviolet light. A region other than the light-shielding pattern transmits the light, and the dry film at the position of the region is cured. In the subsequent development, the mask is removed, and an uncured portion of the dry film is dissolved and removed with an alkaline aqueous solution or the like. The cured portion is not dissolved and not removed but remains, and resist is formed.

The above resist is removed after the etching or blasting.

For example, the providing of the ceramic substrate can include disposing a photoresist on the first surface 11 of the ceramic substrate 10, performing exposure and development on the photoresist through a mask, etching or blasting the ceramic substrate through the photoresist formed in a predetermined pattern by performing the exposure and the development, forming the first arrangement portion 14 by the etching or the blasting, and removing the photoresist from the ceramic substrate.

### (b) Disposing First Conductive Paste

The first conductive paste 15 containing the first metal powder is disposed in the first arrangement portion 14 (FIG. 2B).

The first conductive paste 15 is disposed in the first arrangement portion 14 of the ceramic substrate 10. The first conductive paste 15 is fired to obtain the first conductor 17. The first conductive paste 15 is a member having fluidity, and can be disposed by being applied in close contact with the surface of the first arrangement portion 14. The first arrangement portion 14 is filled with the first conductive paste 15 up to a height exceeding the first planar portion 13. The present disclosure is not limited to such an embodiment, and for example, the first conductive paste 15 can also be applied onto the first planar portion 13 to be disposed on the entire first surface 11.

The first conductive paste 15 disposed in the first arrangement portion 14 includes voids 16 inside or on the first conductive paste 15 (FIG. 2B). The voids 16 can be generated by air bubbles contained in the first conductive paste 15 or air bubbles taken into the first conductive paste 15 when the first conductive paste 15 is disposed in the first arrangement portion 14.

The first conductive paste 15 contains the first metal powder. The first metal powder can contain at least one selected from Ag, Cu, Al, Zn, Sn, Ni, and Ag—Cu alloy. Among them, an Ag—Cu alloy that can be fired at a relatively low temperature in a range from 780° C. to 950° C. is preferable. The first metal powder can also contain Cu, Ag, or the like together with an Ag—Cu alloy having high electrical conductivity. This is because firing can be performed at a temperature lower than the melting points of Ag and Cu, and the first arrangement portion 14 having a thermal conductivity close to that of Ag or Cu 100% can be formed. When the first conductive paste 15 containing the first metal powder is disposed in a through hole 38, the size of the first metal powder is smaller than an inner diameter of the through hole 38. When the first conductive paste 15 containing the first metal powder is disposed in the first arrangement portion 14, the size of the first metal powder is smaller than the depth of the first arrangement portion 14. For example, a median diameter of the first metal powder is preferably in a range from 1 μm to 50 μm, more preferably in a range from 2 μm to 40 μm, and particularly preferably in a range from 5 μm to 30 μm. When the median diameter of the first metal powder is 5 μm or more, aggregation can be suppressed and thermal conductivity can be increased. On the other hand, when the median diameter of the first metal powder is 10 μm or less, the filling property can be enhanced. The shape of the first metal powder is preferably spherical or ellipsoidal from the viewpoint of fluidity, but can be flat or needle-like. This is because the contact between particles can be increased, thermal conductivity can be increased, and the electrical resistance can be decreased by forming the first metal powder into a flat shape or a needle shape.

The first conductive paste 15 can contain at least an active metal powder. The active metal powder can be at least one selected from TiH₂, CeH₂, ZrH₂, and MgH₂. Among them, TiH₂ is preferable. By containing TiH₂, the first conductive paste 15 reacts with nitrogen contained in the ceramic substrate 10 and a metal compound layer is formed as a reaction layer such as TiN at an interface with the ceramic substrate 10. This improves the adhesion between the ceramic substrate 10 and the first conductor 17 obtained by curing the first conductive paste 15.

The first conductive paste 15 can further contain a first organic solvent. Examples of the first organic solvent include those used in general conductive pastes. Examples of the first organic solvent include glycol-based solvents, carbitol-based solvents, and terpineol-based solvents.

The first conductive paste 15 can further contain a first organic resin binder. The viscosity of the first conductive paste 15 can be adjusted depending on the type and amount of the first organic resin binder. The first organic resin binder can be, for example, a solvent generally used as a conductive paste or a resin material such as acrylic, epoxy, urethane, ethyl cellulose, silicone, phenol, polyimide, polyurethane, melamine, or urea. The first organic resin binder is decomposed by firing to be described below, evaporated, and removed.

The first conductive paste 15 can contain a plurality of inorganic fillers other than metals. By containing the inorganic fillers, volume shrinkage during sintering of the first conductive paste 15 can be reduced. Examples of the inorganic fillers that can be used include AlN and Si₃N₄.

When expressed in weight percentage, the first conductive paste 15 preferably contains, for example, an Ag—Cu alloy with a mixing ratio of Ag and Cu of 72:28 in a range from 60% to 99%, TiH₂ as an active metal powder in a range from 0.5% to 10%, an organic binder in a range from 0.1% to 10%, and an inorganic filler in a range from 1% to 20%.

### (c) Firing First Conductive Paste to Obtain First Conductor

The first conductive paste 15 is fired to obtain the first conductor 17 (FIG. 2C).

The firing temperature when the first conductive paste 15 is fired can be in a range from 700° C. to 1200° C., and is preferably in a range from 750° C. to 1100° C., is more preferably in a range from 780° C. to 950° C., and is particularly preferably in a range from 780° C. to 850° C. The firing atmosphere is preferably a vacuum atmosphere of 10-5 Pa or less or an Ar atmosphere of 99.9% or more.

The first conductive paste 15 contracts during the firing process. The stress that tends to contract can be dispersed by the first arrangement portion 14 being rounded.

The first conductor 17 obtained to be a result of firing the first conductive paste 15 has the voids 16 inside and/or on the first conductor 17. The voids 16 in the first conductor 17 can be formed by air bubbles contained in the first conductive paste 15 described above, or can be formed by volatilization of the organic binder in the first conductive paste 15 by firing.

A diameter of the void 16 can be, for example, in a range from 0.5 μm to 200 μm, and is preferably in a range from 3 μm to 100 μm, and is more preferably in a range from 5 μm to 80 μm. The diameter of the void is a volume sphere equivalent diameter.

(d) Polishing or Grinding at least one of First Conductor or Ceramic Substrate

At least one of the first conductor 17 or the ceramic substrate 10 is polished or ground so that the first conductor 17 and the first surface 11 form the same plane. Specifically, a surface 17a of the first conductor 17 and the first planar portion 13 of the first surface 11 form the same plane. The “same plane” is not limited to a case in which the surface 17a of the first conductor 17 and the first planar portion 13 of the first surface 11 are completely on the same plane, and can allow a case in which, in the thickness direction of the ceramic substrate 10, the distance from the second surface 12 of the ceramic substrate 10 to the surface 17a of the first conductor 17 is within +10% of the distance from the second surface 12 of the ceramic substrate 10 to the first planar portion 13 of the first surface 11. For example, the “same plane” can allow a case in which the difference in the distance between the first planar portion 13 of the first surface 11 and the surface 17a of the first conductor 17 is 8 μm or less. By such an operation, the voids 16 in the first conductor 17 are exposed to the surface, and the plurality of first recessed portions 16a are formed in the surface 17a of the first conductor 17 disposed in the first arrangement portion 14 (FIG. 2D).

The polishing and grinding are performed so that the first conductor 17 and the first surface 11 are flush with each other. For example, when the first conductor 17 is present up to a position higher than the first planar portion 13 of the ceramic substrate 10, the polishing or grinding can be performed only on the first conductor 17, or can be performed until both the first conductor 17 and the ceramic substrate 10 are polished or ground. On the other hand, when the first conductor 17 is present only to a position lower than the first planar portion 13 of the ceramic substrate 10, that is, when the first arrangement portion 14 is not completely filled or when an upper surface of the first arrangement portion 14 is recessed, the polishing or grinding can be performed only on the ceramic substrate 10 or can be performed on both the first conductor 17 and the ceramic substrate 10. When the first surface 11 of the ceramic substrate 10 is polished or ground, a surface newly appearing after the polishing or grinding is defined as the first surface 11 of the ceramic substrate 10.

After the polishing or grinding is performed, the plurality of first recessed portions 16a are present on the surface 17a of the first conductor 17. The first recessed portion 16a can be derived from a recessed portion existing on the surface of the first conductor 17 or can be derived from a void existing inside the first conductor 17. The void 16 existing inside the first conductor 17 is exposed on the surface 17a of the first conductor 17 by polishing or grinding to form the first recessed portion 16a.

In plan view, an area of the first recessed portion 16a can be, for example, in a range from 25 μm² to 1 mm², in a range from 50 μm² to 500 μm², or in a range from 80 μm² to 200 μm².

In cross-sectional view, the depth of the first recessed portion 16a can be, for example, in a range from 2 μm to 50 μm, in a range from 5 μm to 40 μm, or in a range from 10 μm to 30 μm.

The area and the depth of the first recessed portion 16a can be measured by observing the upper surface and the cross section of the sintered compact substrate with a laser microscope, respectively. For example, the area and depth of the first recessed portion can be measured using VK-X3000 series manufactured by KEYENCE CORPORATION.

The above polishing or grinding can be performed by, for example, polishing with abrasive grains or grinding using a grindstone in which diamond is embedded.

### (e) Disposing Second Conductive Paste in First Recessed Portion

The second conductive paste 20 containing a second metal powder and a second organic resin binder is disposed in the first recessed portion 16a (FIG. 2E).

The second conductive paste 20 is disposed in the first recessed portion 16a of the first conductor 17. The second conductive paste 20 is cured to obtain the second conductor 21. The second conductive paste 20 is a member having fluidity, and can be provided by being applied in close contact with the surface of the first recessed portion 16a. The first recessed portion 16a is filled with the second conductive paste 20 up to a height exceeding the surface 17a of the first conductor 17.

The second conductive paste 20 contains the second metal powder and the second organic resin binder. The second metal powder can contain at least one selected from Ag, Cu, Al, Zn, Sn, and Ni. Among them, Cu and Ag having high electric conductivity are preferable. The size of the second metal powder is smaller than the depth of the first recessed portion 16a. The median diameter of the second metal powder is preferably in a range from 100 nm to 20 μm, more preferably in a range from 300 nm to 15 μm, and particularly preferably in a range from 500 nm to 10 μm. When the median diameter of the second metal powder is 1 μm or more, aggregation can be suppressed and thermal conductivity can be increased. On the other hand, when the median diameter of the second metal powder is 5 μm or less, the filling property can be enhanced. The shape of the second metal powder is preferably spherical or ellipsoidal from the viewpoint of fluidity, but can be flat or needle-like. This is because the contact between particles can be increased, thermal conductivity can be increased, and the electrical resistance can be decreased by forming the second metal powder into a flat shape or a needle shape.

The content of the second metal powder with respect to the second conductive paste 20 is preferably in a range from 50 wt. % to 95 wt. %, more preferably in a range from 60 wt. % to 95 wt. %, and still more preferably in a range from 70 wt. % to 95 wt. %. By increasing the content of the second metal powder, thermal conductivity of the sintered compact substrate is improved. The resistance of the entire conductive member can be reduced.

The content of the second metal powder with respect to the second conductive paste 20 is preferably in a range from 80 volume % to 99 volume %, more preferably in a range from 85 volume % to 99 volume %, and still more preferably in a range from 90 volume % to 99 volume %. By increasing the content volume of the second metal powder, thermal conductivity of the sintered compact substrate is improved. The resistance of the entire conductive member can be reduced.

The second organic resin binder disperses the second metal powder, suppresses aggregation, improves the fluidity of the second conductive paste, and is cured later. The second organic resin binder can contain, for example, a solvent, a dispersant, a curable resin, and the like. Examples of the curable resin include an epoxy resin, a phenol resin, and a silicone resin.

The second conductive paste 20 can further contain a second organic solvent. Examples of the second organic solvent include those used in general conductive pastes. Examples of the second organic solvent include glycol-based solvents, carbitol-based solvents, and terpineol-based solvents.

When expressed in weight percentage, the second conductive paste 20 can contain, for example, the second metal powder in a range from 50% to 95%, the curable resin in a range from 5% to 40%, and if desired, other components in a range from 0.1% to 10%.

### (f) Curing Second Conductive Paste to Obtain Second Conductor

The second conductive paste 20 is cured to obtain the second conductor 21 (FIG. 2F).

The second conductive paste 20 can be cured by heating or ultraviolet irradiation. The temperature at which the second conductive paste 20 is cured can be in a range from 50° C. to 300° C., and is preferably in a range from 70° C. to 300° C., and is particularly preferably in a range from 80° C. to 250° C.

Since the second conductor 21 contains the second metal powder, the second conductor 21 can have high thermal conductivity and low resistance. Consequently, by filling the first recessed portion 16a with the second conductor 21, the thermal conductivity of the ceramic substrate 10 is improved, and the resistance of the entire conductive member can be reduced.

### (g) Polishing or Grinding Second Conductor

The second conductor 21 is polished or ground so that the second conductor 21 and the first conductor 17 form the same plane (FIG. 2G). Specifically, a surface 21a of the second conductor 21 and the surface 17a of the first conductor 17 form the same plane. The “same plane” is not limited to a case in which the surface 21a of the second conductor 21 and the surface 17a of the first conductor 17 are completely on the same plane, and can allow a case in which, in the thickness direction of the ceramic substrate 10, the height of the surface 21a of the second conductor 21 from the second surface 12 of the ceramic substrate 10 is within +10% of the height of the surface 17a of the first conductor 17 from the second surface 12 of the ceramic substrate 10. For example, the “same plane” can allow a case in which the difference in height between the surface 17a of the first conductor 17 and the surface 21a of the second conductor 21 is 8 μm or less.

Only the second conductor 21 can be polished or ground, both the second conductor 21 and the first conductor 17 can be polished or ground, or the second conductor 21, the first conductor 17, and the ceramic substrate 10 can be polished or ground.

The polishing or grinding is performed so that the second conductor 21 and the first conductor 17 form the same plane. The polishing or grinding is preferably performed so that the second conductor 21, the first conductor 17, and the first surface 11 of the ceramic substrate 10 form the same plane. When the second conductor 21 and the first conductor 17 form the same plane, preferably when the second conductor 21, the first conductor 17, and the first surface 11 of the ceramic substrate 10 form the same plane, the surface of the substrate becomes smooth, resulting in a good appearance. Since the first metal layer 22 to be formed later on the ceramic substrate 10 is uniformly formed, when the ceramic substrate 10, for example, is used as a printed circuit board, variations in the characteristics and shape of each product are reduced, so that reliability is improved. In particular, since the surface of the substrate becomes flat, the mounting stability at the time of mounting a light-emitting element 40 is improved.

The polishing or grinding of the second conductor 21 is performed so that the second metal powder contained in the second conductor 21 is exposed on the surface from a second organic resin cured product obtained by curing the second organic resin binder. When the second metal powder is exposed on the surface, plating is easily attached. That is, the first metal layer 22 to be formed later on the ceramic substrate 10 is easily and uniformly formed, and the adhesion is also improved. Such an effect is more remarkable than when the first metal layer 22 is formed by plating.

The polishing or grinding can be performed only on the second conductor 21, can be performed on the second conductor 21 and the first conductor 17, or can be performed on the second conductor 21, the first conductor 17, and the ceramic substrate 10. When the first surface 11 of the ceramic substrate 10 is polished or ground, a surface newly appearing after the polishing or grinding is defined as the first surface 11 of the ceramic substrate 10.

The above polishing or grinding can be performed by, for example, polishing with abrasive grains or grinding using a grindstone in which diamond is embedded.

After the polishing or grinding, that is, before the first metal layer 22 is formed, an arithmetic mean roughness Ra of the surface 17a of the first conductor 17 and the surface 21a of the second conductor 21 can be, for example, in a range from 100 nm to 2000 nm, preferably in a range from 100 nm to 1500 nm, and more preferably in a range from 100 nm to 1000 nm.

### (h) Forming First Metal Layer

The first metal layer 22 is formed on the surfaces of the first conductor 17 and the polished or ground second conductor 21 (FIG. 2H).

The first metal layer 22 and the second metal powder in the second conductor 21 are electrically connected to each other. Thus, the resistance of the entire conductive member can be reduced. The first metal layer 22 can contain, for example, at least one selected from gold, platinum, palladium, rhodium, nickel, tungsten, molybdenum, chromium, and titanium. The first metal layer 22 can be a single layer or a multilayer. The first metal layer 22 can be formed by, for example, electrolytic plating, electroless plating, vapor deposition, sputtering, or the like. The electrolytic plating or electroless plating is preferable. The first metal layer 22 can also be formed through a mask.

In the manufacturing method of the present disclosure, since the first recessed portion 16a is filled with the second conductor 21 containing the second metal powder, the surface on which the first metal layer 22 is formed is flat, so that the first metal layer 22 is easily formed on the entire first conductor 17. The first metal layer 22 is preferably flat. Since the first metal layer 22 is formed on the entire first conductor 17, corrosion due to sulfidation can be suppressed. Since the second conductor 21 contains the second metal powder and the second metal powder is exposed on the surface of the second conductor 21, the formation of the first metal layer 22 by electrolytic plating or electroless plating can be particularly promoted. The adhesion of the first metal layer 22 is also improved.

An arithmetic mean roughness Ra of the surface of the first metal layer 22 can be, for example, in a range from 100 nm to 2000 nm, preferably in a range from 100 nm to 1500 nm, and more preferably in a range from 100 nm to 1000 nm.

After the first metal layer 22 is formed, an assembly in which the plurality of sintered compact substrates 1 are aligned in a row direction and a column direction is formed. The assembly is cut and separated into the sintered compact substrates 1 that are separated pieces. The cutting can be performed with, for example, a laser or a blade.

### Second Embodiment

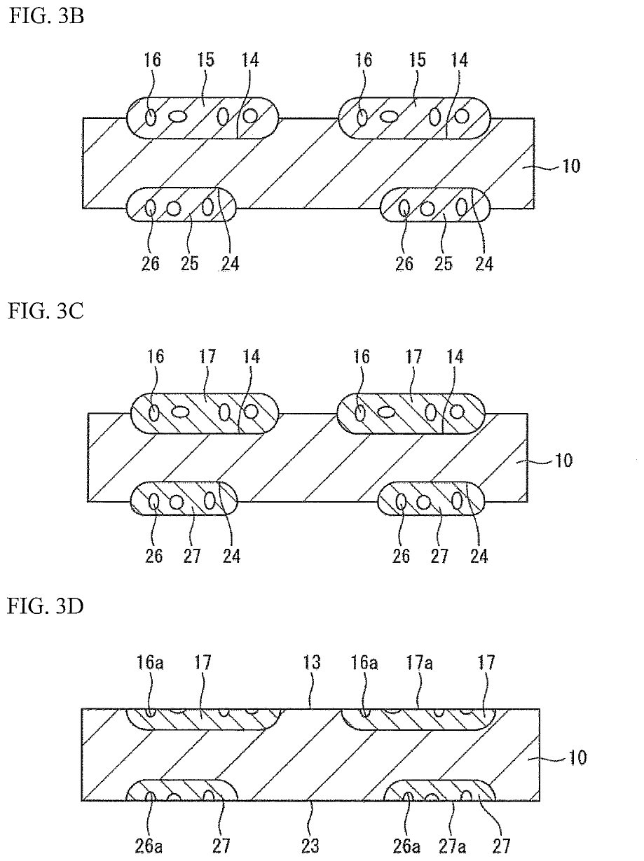

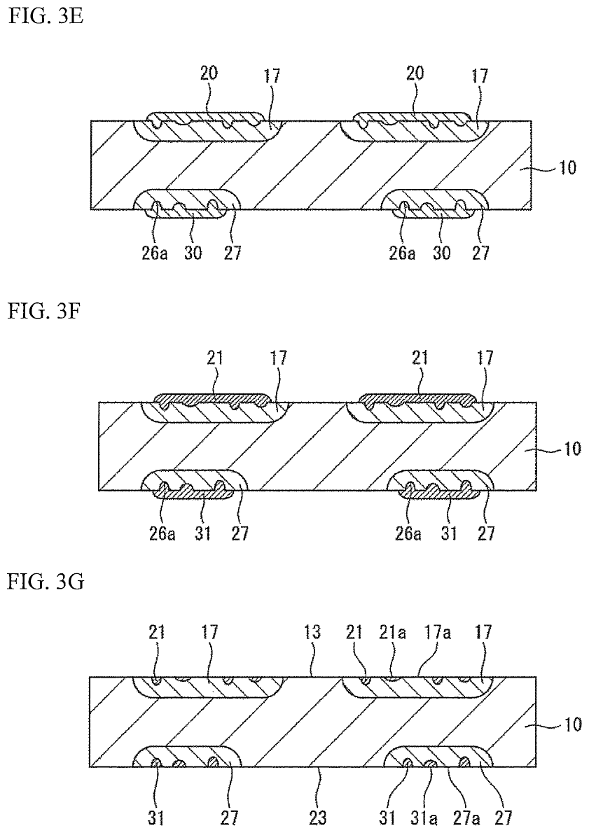

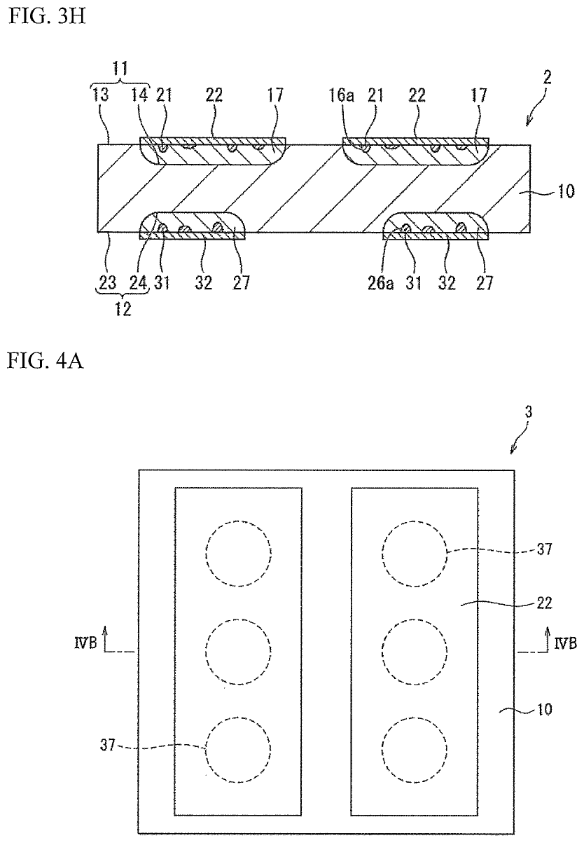

A method for manufacturing a sintered compact substrate 2 according to a second embodiment is described with reference to FIGS. 3A to 3H.

The sintered compact substrate 2 is different from the sintered compact substrate 1 according to the first embodiment in that a third conductor 27, a fourth conductor 31, and a second metal layer 32 are formed.

### Method for Manufacturing Sintered Compact Substrate

The sintered compact substrate 2 of the second embodiment according to the present disclosure includes a ceramic substrate 10 having a first surface 11 and a second surface 12 opposite to the first surface 11 and including a first arrangement portion 14 recessed from a first planar portion 13 of the first surface 11 and a second arrangement portion 24 recessed from a second planar portion 23 of the second surface 12; a first conductor 17 disposed in the first arrangement portion 14; a third conductor 27 disposed in the second arrangement portion 24; a second conductor 21 disposed in a first recessed portion 16a of the first conductor 17; a fourth conductor 31 disposed in a second recessed portion 26a of the third conductor 27; the first metal layer 22 disposed on surfaces of the first conductor 17 and the second conductor 21; and the second metal layer 32 disposed on surfaces of the third conductor 27 and the fourth conductor 31.

The method for manufacturing the sintered compact substrate 2 of the second embodiment according to the present disclosure is different from the method for manufacturing the sintered compact substrate 1 of the first embodiment in that the method includes (a′) providing the ceramic substrate 10 including the ceramic substrate 10 further including the second arrangement portion 24 recessed from the second planar portion 23 of the second surface 12; (b′) disposing a third conductive paste 25 containing a third metal powder in the second arrangement portion 24; (c′) obtaining the third conductor 27 by firing the third conductive paste 25; (d′) forming a plurality of second recessed portions 26a on the surface of the third conductor 27 disposed in the second arrangement portion 24 by polishing or grinding at least one of the third conductor 27 or the ceramic substrate 10 so that the third conductor 27 and the second surface 12 form the same plane; (e′) disposing a fourth conductive paste 30 containing a fourth metal powder and a fourth organic resin binder in the plurality of second recessed portions 26a; (f′) obtaining the fourth conductor 31 by curing the fourth conductive paste 30; (g′) polishing or grinding the fourth conductor 31 so that the fourth conductor 31 and the third conductor 27 form the same plane; and (h′) forming the second metal layer on the surfaces of the third conductor and the polished or ground fourth conductor. The other points are the same as the method for manufacturing the sintered compact substrate 1.

(a′) Providing Ceramic Substrate

The ceramic substrate 10 having the second arrangement portion 24 recessed from the second planar portion 23 of the second surface 12 is provided (FIG. 3A).

The ceramic substrate 10 provided in step (a′) has the first surface 11 and the second surface 12 opposite to the first surface 11. The first surface 11 includes the first planar portion 13 and the first arrangement portion 14 recessed from the first planar portion 13. The second surface 12 includes the second planar portion 23 and the second arrangement portion 24 recessed from the second planar portion 23. That is, the ceramic substrate 10 provided in step (a′) is different from the ceramic substrate provided in step (a) of the first embodiment in that the second surface 12 includes the second arrangement portion 24.

The size and shape of the second arrangement portion 24 can be the same as or different from the size and shape of the first arrangement portion 14. In the present embodiment, the second arrangement portion 24 has the same shape as the first arrangement portion 14 except that a width of the second arrangement portion 24 is narrower than the width of the first arrangement portion 14.

The second arrangement portion 24 in the ceramic substrate 10 can be formed, for example. Alternatively, a substrate on which the second arrangement portion 24 is formed can be purchased as the ceramic substrate 10.

In the case of forming the second arrangement portion 24, the second arrangement portion 24 can be formed by the same method as the first arrangement portion 14, for example, by etching, blasting, or laser processing. Alternatively, a substrate on which the second arrangement portion 24 is formed can be purchased as the ceramic substrate 10.

(b′) Disposing Third Conductive Paste

The third conductive paste 25 containing the third metal powder is disposed in the second arrangement portion 24 (FIG. 3B).

This step (b′) can be performed simultaneously or successively with step (b) in the method for manufacturing the sintered compact substrate 1 of the first embodiment.

The third conductive paste 25 is disposed in the second arrangement portion 24 of the ceramic substrate 10. The third conductive paste 25 is fired to obtain the third conductor 27. The third conductive paste 25 disposed in the second arrangement portion 24 includes voids 26 inside or on the third conductive paste 25 (FIG. 3B). The voids 26 are generated by air bubbles contained in the third conductive paste 25 or air bubbles taken into the third conductive paste 25 when the third conductive paste 25 is disposed in the second arrangement portion 24.

The third conductive paste 25 containing the third metal powder can be the same paste as the first conductive paste 15 containing the first metal powder, and can be disposed in the second arrangement portion 24 in the same method. The third conductive paste 25 is preferably the same as the first conductive paste 15 and is disposed in the second arrangement portion 24 in the same method.

(c′) Firing Third Conductive Paste to Obtain Third Conductor

The third conductive paste 25 is fired to obtain the third conductor 27 (FIG. 3C).

This step (c′) can be performed simultaneously or successively with step (c) in the method for manufacturing the sintered compact substrate 1 of the first embodiment. Preferably, this step (c′) is performed simultaneously with step (c).

The third conductive paste 25 containing the third metal powder is fired by the same method and under the same conditions as those of the first conductive paste 15 containing the first metal powder.

After the firing, the obtained third conductor 27 includes the voids 26 inside and/or on the third conductor 27. The voids 26 in the third conductor 27 are formed by air bubbles contained in the third conductive paste 25 described above, or are formed by volatilization of the organic binder in the third conductive paste 25 by firing.

(d′) Polishing or Grinding at least one of Third Conductor or Ceramic Substrate

At least one of the third conductor 27 or the ceramic substrate 10 is polished or ground so that the third conductor 27 and the second surface 12 form the same plane. Specifically, a surface 27a of the third conductor 27 and the second planar portion 23 of the second surface 12 form the same plane. The “same plane” is not limited to a case in which the surface 27a of the third conductor 27 and the second planar portion 23 of the second surface 12 are completely on the same plane, and can allow a case in which, in the thickness direction of the ceramic substrate 10, the distance from the first surface 11 of the ceramic substrate 10 to the surface 27a of the third conductor 27 is within +10% of the distance from the first surface 11 of the ceramic substrate 10 to the second planar portion 23. For example, the “same plane” can allow a case in which the difference in the distance between the second planar portion 23 of the second surface 12 and the surface 27a of the third conductor 27 is 8 μm or less. By such an operation, the voids 26 in the third conductor 27 are exposed to the surface, and the plurality of second recessed portions 26a are formed in the surface 27a of the third conductor 27 disposed in the second arrangement portion 24 (FIG. 3D).

This step (d′) can be performed simultaneously or successively with step (d) in the method for manufacturing the sintered compact substrate 1 of the first embodiment.

The polishing and grinding are performed in the same manner as the polishing and grinding in step (d). That is, when the third conductor 27 is present up to a position higher than the second planar portion 23 of the ceramic substrate 10, the polishing or grinding can be performed only on the third conductor 27, or can be performed on both the third conductor 27 and the ceramic substrate 10. On the other hand, when the third conductor 27 is present only to a position lower than the second planar portion 23 of the ceramic substrate 10, that is, when the second arrangement portion 24 is not completely filled, the polishing or grinding can be performed only on the ceramic substrate 10 or can be performed on both the third conductor 27 and the ceramic substrate 10. When the second surface 12 of the ceramic substrate 10 is polished or ground, a surface newly appearing after the polishing or grinding is defined as the second surface 12 of the ceramic substrate 10.

After the polishing or grinding is performed, the plurality of second recessed portions 26a are present on the surface 27a of the third conductor 27. The second recessed portion 26a can be derived from a recessed portion existing on the surface of the third conductor 27 or can be derived from a void existing inside the third conductor 27. The void 26 existing inside the third conductor 27 is exposed on the surface of the surface 27a of the third conductor 27 by polishing or grinding to form the second recessed portion 26a.

(e′) Disposing Fourth Conductive Paste in Second Recessed Portion

The fourth conductive paste 30 containing the fourth metal powder and the fourth organic resin binder is disposed in the second recessed portion 26a (FIG. 3E).

The fourth conductive paste 30 is disposed in the second recessed portion 26a of the third conductor 27. The fourth conductive paste 30 is cured to obtain the fourth conductor 31.

This step (e′) can be performed simultaneously or successively with step (e) in the method for manufacturing the sintered compact substrate 1 of the first embodiment.

The fourth conductive paste 30 containing the fourth metal powder can be the same paste as the second conductive paste 20 containing the second metal powder, and can be disposed in the second recessed portion 26a in the same method. The fourth conductive paste 30 is preferably the same as the second conductive paste 20 and is disposed in the second recessed portion 26a in the same method.

### (f) Curing Fourth Conductive Paste to Obtain Fourth Conductor

The fourth conductive paste 30 is cured to obtain the fourth conductor 31 (FIG. 3F).

This step (f′) can be performed simultaneously or successively with step (f) in the method for manufacturing the sintered compact substrate 1 of the first embodiment. Preferably, this step (f) is performed simultaneously with step (f).

The fourth conductive paste 30 containing the fourth metal powder is fired by the same method and under the same conditions as those of the second conductive paste 20 containing the second metal powder.

(g′) Polishing or Grinding Fourth Conductor

The fourth conductor 31 is polished or ground so that the fourth conductor 31 and the third conductor 27 form the same plane. Specifically, a surface 31a of the fourth conductor 31 and the surface 27a of the third conductor 27 form the same plane (FIG. 3G). The “same plane” is not limited to a case in which the surface 31a of the fourth conductor 31 and the surface 27a of the third conductor 27 are completely on the same plane, and can allow a case in which, in the thickness direction of the ceramic substrate 10, the distance from the first surface 11 of the ceramic substrate 10 to the surface 31a of the fourth conductor 31 is within +10% of the distance from the first surface 11 of the ceramic substrate 10 to the surface 27a of the third conductor 27. For example, the “same plane” can allow a case in which the difference in the distance between the surface 27a of the third conductor 27 and the surface 31a of the fourth conductor 31 is 8 μm or less.

This step (g′) can be performed simultaneously or successively with step (g) in the method for manufacturing the sintered compact substrate 1 of the first embodiment.

The polishing and grinding are performed in the same manner as the polishing and grinding in step (g). For example, only the fourth conductor 31 can be polished or ground, the fourth conductor 31 and the third conductor 27 can be polished or ground, or the fourth conductor 31, the third conductor 27, and the ceramic substrate 10 can be polished or ground.

The polishing or grinding is performed so that the fourth conductor 31 and the third conductor 27 form the same plane. The polishing or grinding is preferably performed so that the fourth conductor 31, the third conductor 27, and the second surface 12 of the ceramic substrate 10 form the same plane. When the fourth conductor 31 and the third conductor 27 form the same plane, preferably when the fourth conductor 31, the third conductor 27, and the second surface 12 of the ceramic substrate 10 form the same plane, the surface of the substrate becomes smooth, resulting in a good appearance. Since the second metal layer 32 to be formed later on the ceramic substrate 10 is uniformly formed, when the ceramic substrate 10, for example, is used as a printed circuit board, variations in the characteristics and shape of each product are reduced, so that reliability is improved.

By polishing or grinding the fourth conductor 31, the fourth metal powder contained in the fourth conductor 31 is exposed on the surface. When the fourth metal powder is exposed on the surface, plating is easily attached. That is, the second metal layer 32 to be formed later on the ceramic substrate 10 is easily and uniformly formed, and the adhesion with the second metal layer 32 is also improved. Such an effect is more remarkable when the second metal layer 32 is formed by plating.

The polishing or grinding can be performed only on the fourth conductor 31, can be performed on the fourth conductor 31 and the third conductor 27, or can be performed on the fourth conductor 31, the third conductor 27, and the ceramic substrate 10. When the second surface 12 of the ceramic substrate 10 is polished or ground, a surface newly appearing after the polishing or grinding is defined as the second surface 12 of the ceramic substrate 10.

(h′) Forming Second Metal Layer

The second metal layer 32 is formed on the surfaces of the third conductor 27 and the polished or ground fourth conductor 31 (FIG. 3H).

This step (h′) can be performed simultaneously or successively with step (h) in the method for manufacturing the sintered compact substrate 1 of the first embodiment. Preferably, this step (h′) is performed simultaneously with step (h).

The second metal layer 32 is formed by a similar method and using a metal, an alloy, or the like similar to those of the first metal layer 22. Preferably, the second metal layer 32 is formed by the same method and using the same metal or alloy as the first metal layer 22.

In the manufacturing method of the present disclosure, since the second recessed portion 26a is filled with the fourth conductor 31 containing the fourth metal powder, the surface on which the second metal layer 32 is formed is flat, so that the second metal layer 32 is easily formed on the entire third conductor 27. Since the second metal layer 32 is formed on the entire third conductor 27, corrosion due to sulfidation can be suppressed. Since the fourth conductor 31 contains the fourth metal powder and the fourth metal powder is exposed on the surface of the fourth conductor 31, the formation of the second metal layer 32 by electrolytic plating or electroless plating can be particularly promoted. The adhesion of the second metal layer 32 is also improved.

### Third Embodiment

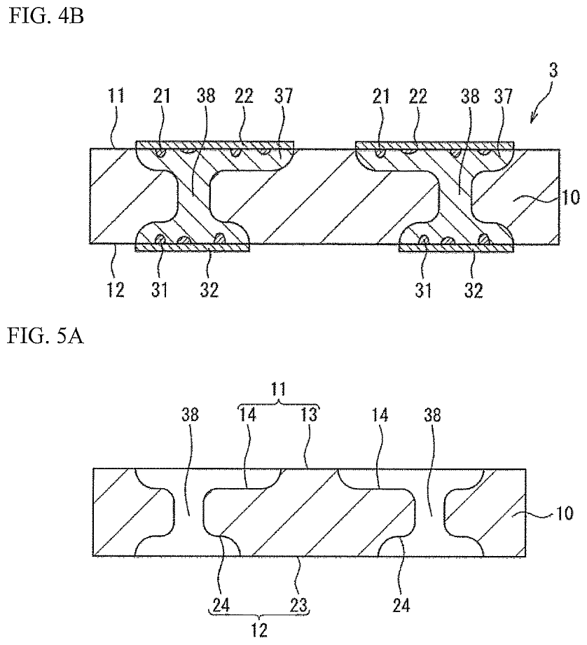

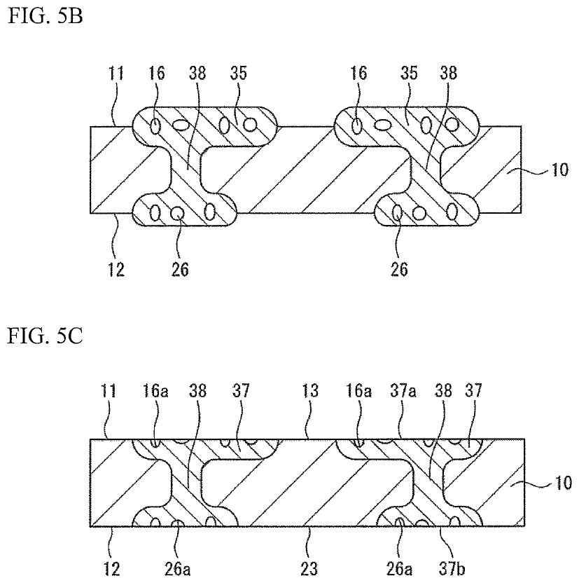

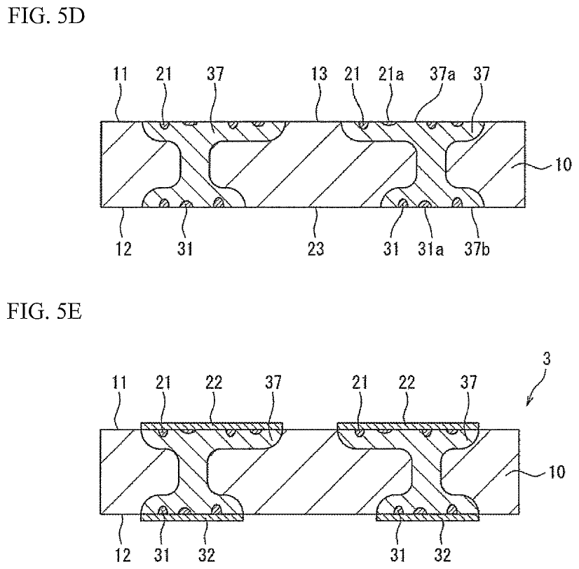

A method for manufacturing a sintered compact substrate 3 according to the third embodiment is described with reference to FIGS. 4A and 4B and FIGS. 5A to 5E.

The sintered compact substrate 3 is different from the sintered compact substrate 2 according to the second embodiment in that the ceramic substrate 10 has a through hole 38 connecting the first surface 11 and the second surface 12. In the illustrated example, the through hole 38 connects the first arrangement portion 14 and the second arrangement portion 24.

### Method for Manufacturing Sintered Compact Substrate

A method for manufacturing the sintered compact substrate 3 of the third embodiment according to the present disclosure is a method for manufacturing the sintered compact substrate 3 including: a ceramic substrate 10 having a first surface 11 and a second surface 12 opposite to the first surface 11 and including a first arrangement portion 14 recessed from a first planar portion 13 of the first surface 11, a second arrangement portion 24 recessed from a second planar portion 23 of the second surface 12, and a through hole 38 connecting the first surface 11 and the second surface 12; a fifth conductor 37 disposed in the first arrangement portion 14, the second arrangement portion 24, and the through hole 38; a second conductor 21 disposed in a first recessed portion 16a located on a surface of the fifth conductor 37 proximate to the first surface 11; a fourth conductor 31 disposed in a second recessed portion 26a located on a surface of the fifth conductor 37 proximate to the second surface 12; a first metal layer 22 disposed on the surface of the fifth conductor 37 proximate to the first surface 11 and a surface of the second conductor 21; and a second metal layer 32 disposed on the surface of the fifth conductor 37 proximate to the second surface 12 and a surface of the fourth conductor 31. The fifth conductor 37 serves as the first conductor and the third conductor.

The method for manufacturing the sintered compact substrate 3 of the third embodiment according to the present disclosure is different from the method for manufacturing the sintered compact substrate 2 of the second embodiment in that the method includes (a″) providing the ceramic substrate 10 including the ceramic substrate 10 further including the through hole 38 connecting the first surface 11 and the second surface 12; and (x) performing disposing the fifth conductive paste 35 in the first arrangement portion 14, disposing the fifth conductive paste 35 in the second arrangement portion 24, and disposing the fifth conductive paste 35 in the through hole 38 at the same time, that is, disposing the fifth conductive paste 35 containing a fifth metal powder in the first arrangement portion 14, the second arrangement portion 24, and the through hole 38, and subsequently forming the fifth conductor 37 by firing the fifth conductive paste 35. The other points are the same as the method for manufacturing the sintered compact substrate 2.

(a″) Providing Ceramic Substrate

For the ceramic substrate 10, a ceramic substrate 10 including the through hole 38 connecting the first surface 11 and the second surface 12 is provided (FIG. 5A).

The ceramic substrate 10 provided in step (a″) has the first surface 11 and the second surface 12 opposite to the first surface 11 and includes the through hole 38 connecting the first surface 11 and the second surface 12. The first surface 11 includes the first planar portion 13 and the first arrangement portion 14 recessed from the first planar portion 13. The second surface 12 includes the second planar portion 23 and the second arrangement portion 24 recessed from the second planar portion 23. That is, the ceramic substrate 10 provided in step (a″) is different from the ceramic substrate provided in step (a′) of the second embodiment in that the ceramic substrate 10 includes the through hole 38 connecting the first surface 11 and the second surface 12.

In the illustrated example, the through hole 38 connects the first arrangement portion 14 and the second arrangement portion 24, but is not limited thereto as long as the through hole 38 connects the first surface 11 and the second surface 12. For example, the through hole 38 can connect the first planar portion 13 of the first surface 11 and the second planar portion 23 of the second surface 12, can connect the first arrangement portion 14 of the first surface 11 and the second planar portion 23 of the second surface 12, or can connect the first planar portion 13 of the first surface 11 and the second arrangement portion 24 of the second surface 12.

In the illustrated example, three through holes 38 are arranged side by side in the long direction on the bottom surfaces defining the first arrangement portion 14 and the second arrangement portion 24.

In cross-sectional view in the thickness direction of the ceramic substrate 10 in which the through hole 38 is disposed, a connection portion between the through hole 38 and the inner surface defining the first arrangement portion 14 and a connection portion between the through hole 38 and an inner surface defining the second arrangement portion 24 can be rounded.

The through hole 38 can be formed by laser processing, for example, CO2 laser processing, machining, or the like. A substrate formed with the through hole 38 can be purchased as the ceramic substrate 10.

### (x) Disposing Fifth Conductive Paste and Firing Fifth Conductive Paste to Form Fifth Conductor

The fifth conductive paste 35 is disposed in the first arrangement portion 14, the second arrangement portion 24, and the through hole 38 and fired to form the fifth conductor 37 (FIG. 5B).

The fifth conductive paste 35 serves as the first conductive paste and the third conductive paste, and is further filled into the through hole 38. In other words, by disposing the fifth conductive paste 35 in the first arrangement portion 14, the second arrangement portion 24, and the through hole 38, the first conductive paste is disposed in the first arrangement portion 14 and the third conductive paste is disposed in the second arrangement portion 24.

The fifth conductive paste 35 containing the fifth metal powder can be the same paste as the first conductive paste 15 containing the first metal powder, and can be disposed in the same method.

Subsequently, the fifth conductive paste 35 is fired to form the fifth conductor 37.

The fifth conductor 37 serves as the first conductor 17 and the third conductor 27, and is also present in the through hole 38. In other words, by forming the fifth conductor 37 in the first arrangement portion 14, the second arrangement portion 24, and the through hole 38, the first conductor 17 is disposed in the first arrangement portion 14 and the third conductor 27 is disposed in the second arrangement portion 24.

The fifth conductive paste 35 containing the fifth metal powder is fired by the same method and under the same conditions as those of the first conductive paste 15 containing the first metal powder.

After the firing, the obtained fifth conductor 37 includes the voids 16 and 26 inside and/or on the fifth conductor 37. The voids 16 and 26 in the fifth conductor 37 are formed by air bubbles contained in the fifth conductive paste 35 described above, or are formed by volatilization of the organic binder in the fifth conductive paste 35 by firing. The void 16 is a void located proximate to the first surface 11, that is, a void in the fifth conductor 37 serving as the first conductor 17. The void 26 is a void located proximate to the second surface 12, that is, a void in the fifth conductor 37 serving as the third conductor 27.

Subsequently, the sintered compact substrate 3 can be manufactured in the same manner as in the method for manufacturing the sintered compact substrate 2 of the second embodiment.

Specifically, the same operations as in steps (d) and (d′) above are performed, and at least one of the fifth conductor 37 or the ceramic substrate 10 is polished or ground so that the fifth conductor 37 and the first surface 11 form the same plane and the fifth conductor 37 and the second surface 12 form the same plane (FIG. 5C).

Subsequently, the same operations as in steps (e), (e′), (f), (f), (g), and (g′) above are performed to form the second conductor 21 in the first recessed portion 16a and form the fourth conductor 31 in the second recessed portion 26a. The surface 21a of the second conductor 21 and a surface 37a of the fifth conductor 37 form the same plane, and the surface 31a of the fourth conductor 31 and a surface 37b of the fifth conductor 37 form the same plane (FIG. 5D). Preferably, the surface 21a of the second conductor 21, the surface 37a of the fifth conductor 37, and the first surface 11 of the ceramic substrate 10 form the same plane, and the surface 31a of the fourth conductor 31, the surface 37b of the fifth conductor 37, and the second surface 12 of the ceramic substrate 10 form the same plane.

Subsequently, the same operations as in steps (h) and (h′) above are performed to form the first metal layer 22 on the surface 37a of the fifth conductor 37 and the polished or ground surface of the second conductor 21, and to form the second metal layer 32 on the surface 37b of the fifth conductor 37 and the polished or ground surface of the fourth conductor 31 (FIG. 5E).

### Light-Emitting Device

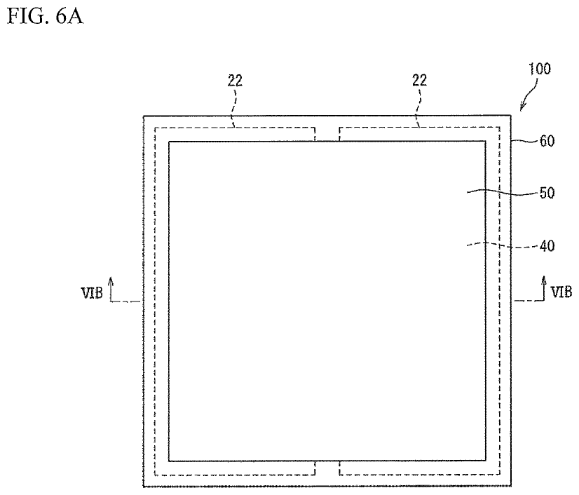

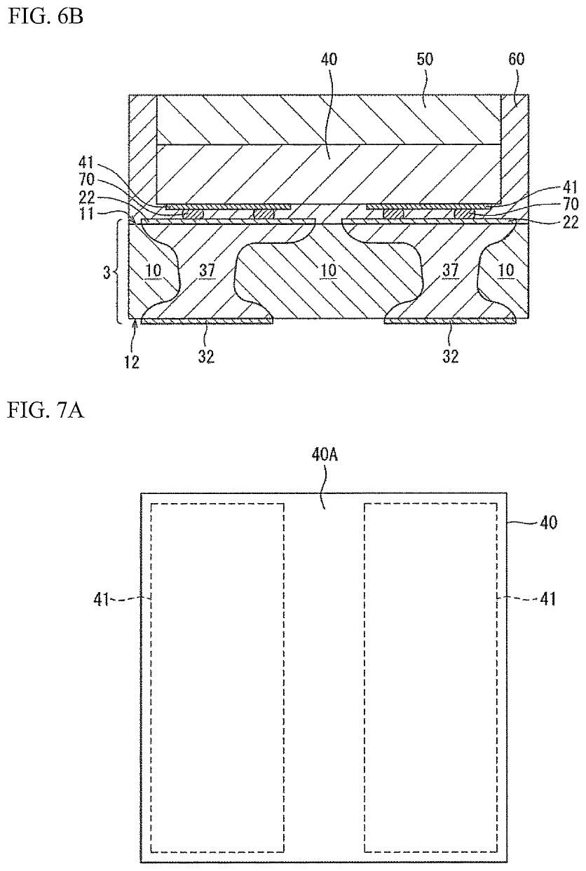

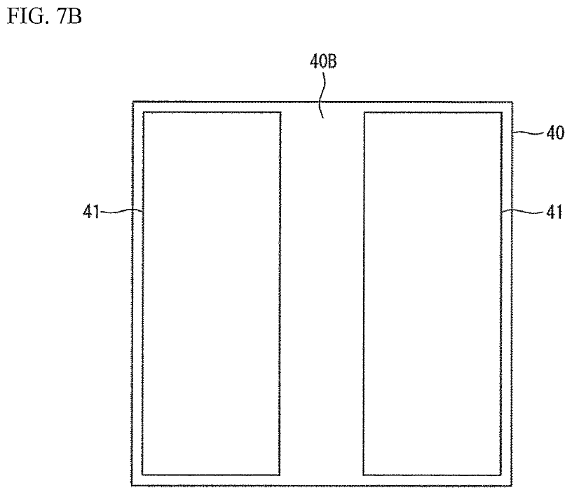

A light-emitting device 100 according to an embodiment is described below with reference to FIGS. 6A and 6B and FIGS. 7A and 7B. FIG. 6A is a schematic plan view illustrating the light-emitting device 100. FIG. 6B is a schematic cross-sectional view illustrating a cross section taken along line VIB-VIB in FIG. 6A. FIG. 7A is a schematic plan view illustrating the light-emitting element 40. FIG. 7B is a schematic bottom view illustrating the light-emitting element 40.

The light-emitting device 100 includes the sintered compact substrate 3 of the present disclosure and the light-emitting element 40 disposed on the sintered compact substrate 3 and including element electrodes 41, and the element electrode 41 and the first metal layer 22 are electrically connected to each other. The light-emitting element 40 is disposed on the first metal layers 22. The light-emitting device 100 further includes a light-transmissive member 50 disposed on an upper surface of the light-emitting element 40, and a covering member 60 that covers the light-emitting element 40 and the light-transmissive member 50 with an upper surface of the light-transmissive member 50 being exposed. The light-emitting device 100 includes one light-emitting element 40, for example. Each component of the light-emitting device 100 is described below.

### Sintered Compact Substrate

A sintered compact substrate can be, for example, the sintered compact substrate 3 according to the third embodiment. The sintered compact substrate 3 includes a ceramic substrate 10 having a first surface 11 and a second surface 12 opposite to the first surface 11 and including a first arrangement portion 14 recessed from a first planar portion 13 of the first surface 11, a second arrangement portion 24 recessed from a second planar portion 23 of the second surface 12, and a through hole 38 connecting the first surface 11 and the second surface 12; a fifth conductor 37 disposed in the first arrangement portion 14, the second arrangement portion 24, and the through hole 38; a second conductor 21 disposed in a first recessed portion 16a located on a surface of the fifth conductor 37 proximate to the first surface 11; a fourth conductor 31 disposed in a second recessed portion 26a located on a surface of the fifth conductor 37 proximate to the second surface 12; a first metal layer 22 disposed on the surface of the fifth conductor 37 proximate to the first surface 11 and a surface of the second conductor 21; and a second metal layer 32 disposed on the surface of the fifth conductor 37 proximate to the second surface 12 and a surface of the fourth conductor 31. The light-emitting element 40 is disposed on the sintered compact substrate 3 with the first surface 11 as an upper surface. A portion of the fifth conductor 37 proximate to the upper surface and the first metal layer 22 each have a size and a shape that allow the element electrode 41 of the light-emitting element 40 to be disposed.

### Light-Emitting Element

The light-emitting element 40 is a member that is supplied with power and emits light. A shape of the light-emitting element 40 in plan view is, for example, rectangular. The light-emitting element 40 includes a semiconductor layered body. A light-transmissive substrate made of sapphire, gallium nitride, or the like is disposed on the upper surface of the semiconductor layered body. A pair of the element electrodes 41 are provided on the lower surface of the semiconductor layered body. For the semiconductor layered body, a predetermined composition can be used in accordance with a desired emission wavelength. For example, a nitride semiconductor (InₓAl_{y}Ga_{1-x-y}N, 0≤ X, 0≤Y, X+Y≤1) or GaP, which can emit blue or green light, or GaAlAs or AlInGaP, which can emit red light, can be used. The size and the shape of the light-emitting element 40 can be appropriately selected in accordance with the purpose of use.

The pair of element electrodes 41 each have a rectangular shape in plan view, for example, and are exposed on a lower surface 40B of the light-emitting element 40. The element electrode 41 can be formed of, for example, a single-layer film or a layered film of a metal such as gold, platinum, palladium, rhodium, nickel, tungsten, molybdenum, chromium, or titanium, or an alloy thereof.

The element electrode 41 is connected to the fifth conductor 37 via conductive members 70 and the first metal layer 22. That is, the element electrode 41 is indirectly electrically connected to the fifth conductor 37. The conductive member 70 can be, for example, a bump made of gold, solder, or the like. The element electrode 41 and the first metal layer 22 can be connected by, for example, printing and disposing solder or the like on the entire electrode surface without providing the bump.

### Light-Transmissive Member

The light-transmissive member 50 is a member that protects an upper surface 40A of the light-emitting element 40 and is located on a light extraction surface of the light-emitting device 100. The light-transmissive member 50 has a rectangular shape, for example, and has the same size and shape as those of the light-emitting element 40 in plan view. The light-transmissive member 50 can have a shape and a size including the light-emitting element 40 in plan view.

The light-transmissive member 50 is made of, for example, a light-transmissive resin material. An epoxy resin, a silicone resin, a resin in which these resins are mixed, or the like can be used for the light-transmissive resin material. The light-transmissive member 50 can contain a phosphor. For example, when the light-transmissive member 50 contains a phosphor that absorbs blue light from the light-emitting element 40 and emits yellow light, white light can be emitted from the light-emitting device 100. The light-transmissive member 50 can contain a plurality of types of phosphors. For example, when the light-transmissive member 50 contains a phosphor that absorbs blue light from the light-emitting element 40 and emits green light and a phosphor that emits red light, white light can also be emitted from the light-emitting device 100.

The light-transmissive member 50 can further contain a light-emitting material such as a phosphor or a quantum dot. Examples of such a phosphor include yttrium-aluminum (gallium-doped) garnet activated with cerium, nitrogen-containing calcium (strontium) aluminosilicate activated with europium, potassium fluorosilicate activated with manganese, and a β-SiAlON phosphor. Specific examples of the phosphor include an yttrium aluminum garnet phosphor (for example, (Y,Gd)₃(Al,Ga)₅O₁₂:Ce), a lutetium aluminum garnet phosphor (for example, Lu₃(Al,Ga)₅O₁₂:Ce), a terbium aluminum garnet phosphor (for example, Tb₃(Al,Ga)₅O₁₂:Ce), a CCA phosphor (for example, Ca₁₀(PO₄)₆Cl₂:Eu), an SAE phosphor (for example, Sr₄Al₁₄O₂₅:Eu), a chlorosilicate phosphor (for example, Ca₈MgSi₄O₁₆Cl₂:Eu), a silicate phosphor (for example, (Ba,Sr,Ca,Mg)₂SiO₄:Eu), oxynitride phosphors such as a β-SiAlON phosphor (for example, (Si,Al)₃(O,N)₄:Eu) or an α-SiAlON phosphor (for example, Ca(Si,Al)₁₂(O,N)₁₆:Eu), nitride phosphors such as an LSN phosphor (for example, (La,Y)₃Si₆N₁₁:Ce), a BSESN phosphor (for example, (Ba,Sr)₂Si₅N₈:Eu), an SLA phosphor (for example, SrLiAl₃N₄:Eu), a CASN phosphor (for example, CaAlSiN₃:Eu), or an SCASN phosphor (for example, (Sr,Ca)AlSiN₃:Eu), fluoride phosphors such as a KSF phosphor (for example, K₂SiF₆:Mn), a KSAF phosphor (for example, K₂(Si₁₋ₓAlₓ)F₆₋ₓ:Mn, where x satisfies 0<x<1), or an MGF phosphor (for example, 3.5MgO·0.5MgF₂·GeO₂:Mn), and the like. Examples of the quantum dots include quantum dots having a perovskite structure (for example, (Cs,FA,MA)(Pb,Sn)(F,Cl,Br,I)₃, where FA represents formamidinium and MA represents methylammonium), II-VI group quantum dots (for example, CdSe), III-V group quantum dots (for example, InP), quantum dots having a chalcopyrite structure (for example, (Ag,Cu)(In,Ga)(S,Se)₂), and the like.

### Covering Member

The covering member 60 is a member that is disposed on an upper surface of the sintered compact substrate 3 and covers and protects lateral surfaces of the light-emitting element 40 and the light-transmissive member 50. The covering member 60 is disposed with an upper surface of the light-transmissive member 50 being exposed. The covering member 60 also covers lateral surfaces of the element electrodes 41 and the conductive members 70 by entering between the light-emitting element 40 and the sintered compact substrate 3.

The covering member 60 can be formed of a resin having light reflectivity, light transmissivity, a light blocking property, or the like, any of these resins containing a light reflective substance, or the like. The covering member 60 preferably has at least any of light reflectivity and a light blocking property. Examples of the resin include a resin containing one or more of a silicone resin, a modified silicone resin, an epoxy resin, a modified epoxy resin, and an acrylic resin, and a hybrid resin. Examples of the light reflective substance include titanium oxide, silicon oxide, zirconium oxide, potassium titanate, aluminum oxide, aluminum nitride, boron nitride, and mullite. The covering member 60 can contain a phosphor, a diffusing material, a colorant, and the like.

In the light-emitting device 100, the heat dissipation against a temperature rise due to driving can be improved by the sintered compact substrate 3 in which the fifth conductor 37 is embedded in the first arrangement portion 14 and the second arrangement portion 24. In particular, since the fifth conductor 37 includes the second conductor 21 containing the second metal powder and the fourth conductor 31 containing the fourth metal powder in the first recessed portion 16a and the second recessed portion 26a, respectively, on the surface of the sintered compact substrate 3, the fifth conductor 37 exhibits higher heat dissipation properties.

### Method for Manufacturing Light-Emitting Device

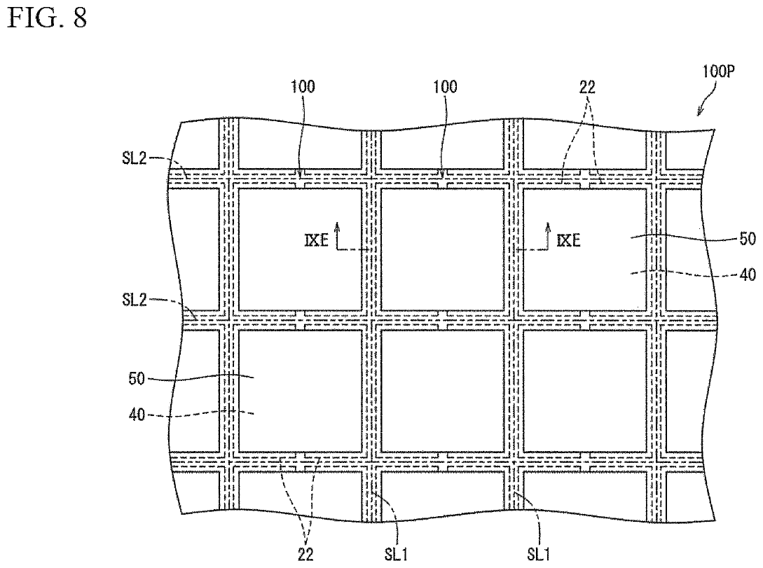

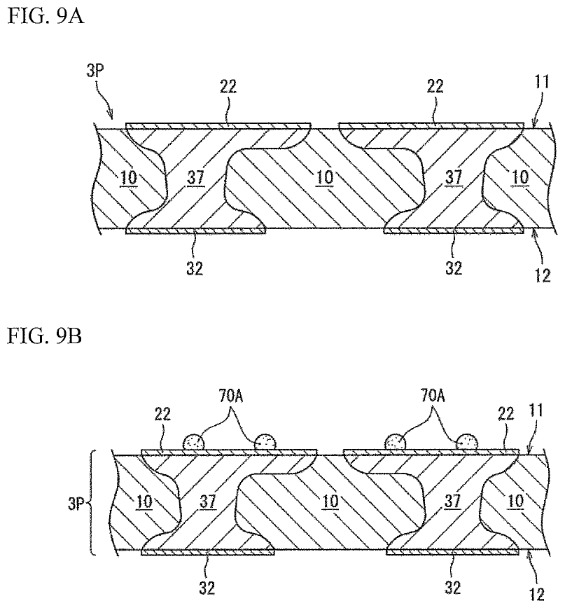

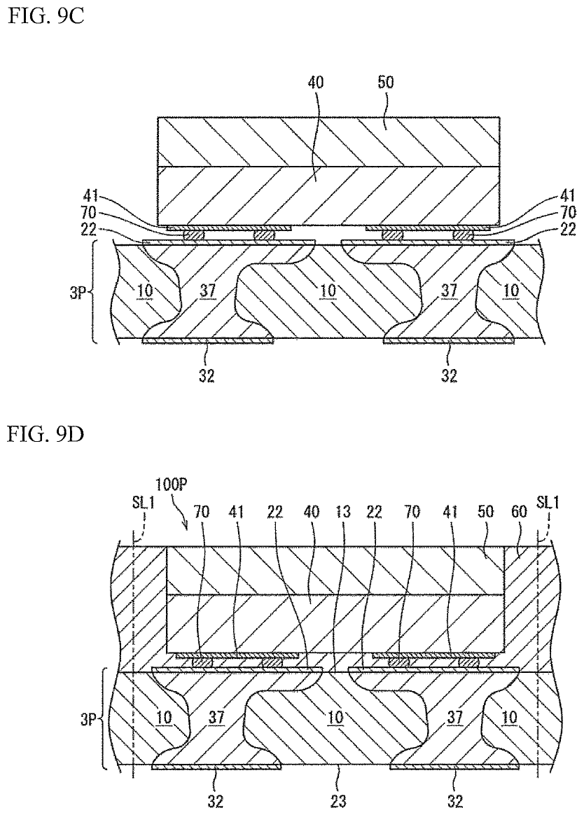

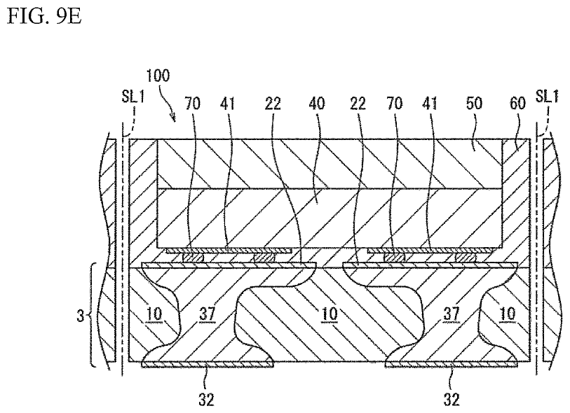

A method for manufacturing the light-emitting device is described below with reference to FIGS. 8 and 9A to 9E. FIG. 8 is a schematic plan view illustrating an assembly 100P of the light-emitting devices 100 before singulation. FIG. 9A is a schematic cross-sectional view illustrating an assembly 3P of the sintered compact substrates 3 having been provided. FIG. 9B is a schematic cross-sectional view illustrating a state in which conductive members 70A are disposed. FIG. 9C is a schematic cross-sectional view illustrating a state in which the light-emitting element 40 is disposed. FIG. 9D is a schematic cross-sectional view illustrating a state in which the covering member 60 is disposed. FIG. 9E is a schematic cross-sectional view illustrating the light-emitting device 100 obtained by singulation.

The method for manufacturing the light-emitting device includes providing a sintered compact substrate obtained by the method for manufacturing the sintered compact substrate, and disposing the light-emitting element 40 including an element electrode on the first metal layer 22, and in the step of disposing the light-emitting element, the first metal layer 22 and the light-emitting element 40 are directly or indirectly electrically connected to each other. The manufacturing method further includes disposing the conductive members 70A, forming the covering member 60 covering the light-emitting element 40 and the light-transmissive member 50 in a state in which the upper surface of the light-transmissive member 50 disposed on the upper surface of the light-emitting element 40 is exposed, and performing singulation. Each configuration of the method for manufacturing the light-emitting device is described below.

In the description of the method for manufacturing the light-emitting device, the assembly 100P in which a plurality of the light-emitting devices 100 are aligned in the row direction and the column direction is manufactured. By cutting the assembly 100P along cutting lines SL1 and SL2, the light-emitting devices 100 can be obtained.

### Preparing Sintered Compact Substrate

As an example, the assembly 3P of the sintered compact substrates 3 manufactured by the method for manufacturing the sintered compact substrate of the third embodiment is provided. In the sintered compact substrate 3, the first surface 11 on which the light-emitting element 40 is disposed is defined as an upper surface. The fifth conductor 37 and the first metal layer 22 are formed in accordance with the size and arrangement of the light-emitting element 40, an interval between the pair of element electrodes 41, and the like.

### Disposing Conductive Members

The conductive members 70A before joining are disposed on the first metal layer 22 on the upper surface of the assembly 3P.

### Disposing Light-Emitting Element

The light-emitting elements 40 are disposed with the element electrodes 41 facing the assembly 3P. The light-emitting elements 40 are aligned in the row direction and the column direction over the assembly 3P. The element electrodes 41 can be indirectly electrically connected to the assembly 3P via the conductive member 70 and the first metal layer 22.

The light-transmissive member 50 is disposed in advance on the upper surface of the light-emitting element 40. The light-transmissive member 50 can be disposed by applying an uncured material for the light-transmissive member 50 by, for example, potting, spraying, inkjetting, printing, or the like, and then curing the material. For the light-transmissive member 50, a member formed into a sheet shape or a plate shape can be disposed on the upper surface of the light-emitting element 40 via an adhesive. The light-transmissive member 50 can be disposed on the upper surface of the light-emitting element 40 after the light-emitting element 40 on which the light-transmissive member 50 is not disposed in advance is disposed on the sintered compact substrate 3.

### Disposing Covering Member

The covering member 60 is disposed on the upper surface of the assembly 3P of the sintered compact substrates 3 so that the upper surfaces of the light-transmissive members 50 are exposed. The covering member 60 preferably covers the lateral surfaces of the light-emitting element 40 and the light-transmissive member 50, and preferably also covers the lower surface of the light-emitting element 40 and the lateral surface of the conductive member 70. The covering member 60 can be disposed, for example, by disposing a nozzle of a resin discharge device above the assembly 3P, applying an uncured resin material by moving the nozzle while discharging the uncured resin material from a tip of the nozzle, and then curing the material. The covering member 60 is preferably applied in a plurality of batches.

An upper surface of the covering member 60 is preferably formed to be flush with the upper surface of the light-transmissive member 50. The covering member 60 disposed between the adjacent light-emitting elements 40 and the adjacent light-transmissive members 50 can have an upper surface partially recessed or raised. By polishing, grinding, or the like the raised covering member 60, the upper surface of the covering member 60 can also be formed to be flush with the upper surface of the light-transmissive member 50. In this case, not only the upper surface of the covering member 60 but also an upper portion of the light-transmissive member 50 can be polished, ground, or the like. After disposing the covering member 60, the assembly 100P in which the plurality of light-emitting devices 100 are aligned in the row direction and the column direction is formed.

### Performing Singulation

The assembly 100P of the light-emitting devices is cut and separated into the light-emitting devices 100 that are separated pieces. The cutting lines SL1 and SL2 to be aimed for cutting are positioned in a lattice shape on the covering member 60 in plan view. The cutting can be performed with, for example, a laser or a blade.

1. A method for manufacturing a sintered compact substrate, the method comprising:
providing a ceramic substrate having a first surface and a second surface opposite to the first surface, the ceramic substrate having a first arrangement portion recessed from a first planar portion of the first surface;
disposing a first conductive paste containing a first metal powder in the first arrangement portion;
obtaining a first conductor by firing the first conductive paste;
forming a plurality of first recessed portions on a surface of the first conductor disposed in the first arrangement portion by polishing or grinding at least one of the first conductor or the ceramic substrate so that the first conductor and the first surface form a same plane;
disposing a second conductive paste containing a second metal powder and a second organic resin binder in the plurality of first recessed portions;
obtaining a second conductor by curing the second conductive paste;
polishing or grinding the second conductor so that the second conductor and the first conductor form the same plane; and
forming a first metal layer on surfaces of the first conductor and the polished or ground second conductor.

2. The method according to claim 1, wherein in polishing or grinding the second conductor, the second metal powder is exposed from a second organic resin cured product obtained by curing the second organic resin binder.

3. The method according to claim 1, wherein in providing the ceramic substrate, the ceramic substrate comprises a through hole connecting the first surface and the second surface.

4. The method according to claim 3, wherein in providing the ceramic substrate, at least a part of the first arrangement portion and the through hole is formed by laser processing.

5. The method according to claim 1, wherein in disposing the first conductive paste, the first conductive paste further contains at least a first active metal powder.

6. The method according to claim 5, wherein in disposing the first conductive paste, the first active metal powder contains at least one selected from TiH₂, CeH₂, ZrH₂, and MgH₂.

7. The method according to claim 1, wherein in disposing the first conductive paste, the first metal powder contains at least one selected from Ag, Cu, Al, Zn, Sn, Ni, and Ag—Cu alloy powder.

8. The method according to claim 1, wherein in disposing the second conductive paste, the second conductive paste further contains a second organic solvent.

9. The method according to claim 1, wherein in disposing the second conductive paste, the second metal powder contains at least one of Ag, Cu, Al, Zn, Sn, or Ni.

10. The method according to claim 1, wherein in disposing the second conductive paste, a content of the second metal powder with respect to the second conductive paste is in a range from 50 wt. % to 95 wt. %.

11. The method according to claim 1, wherein in disposing the second conductive paste, a content of the second metal powder with respect to the second conductive paste is in a range from 80 volume % to 99 volume %.

12. The method according to claim 1, wherein in disposing the first conductive paste, the first conductive paste further contains a first organic resin binder.

13. The method according to claim 1, wherein in disposing the first conductive paste, the first conductive paste further contains an inorganic filler other than a metal.

14. The method according to claim 1, wherein in obtaining the first conductor, a firing temperature is in a range from 700° C. to 1200° C.

15. The method according to claim 1, wherein in obtaining the first conductor, a firing atmosphere is a vacuum atmosphere or an Ar atmosphere of 99.9% or more.

16. The method according to claim 1, wherein in obtaining the second conductor, a curing temperature is in a range from 50° C. to 300° C.

17. The method according to claim 1, wherein in providing the ceramic substrate,
a photoresist is disposed on the first surface of the ceramic substrate;
exposure and development are performed on the photoresist through a mask;
the ceramic substrate is etched or blasted through the photoresist formed in a predetermined pattern by performing the exposure and the development;
the first arrangement portion is formed by the etching or the blasting; and
the photoresist is removed from the ceramic substrate.

18. The method according to claim 1, wherein in forming the first metal layer, the first metal layer contains at least one selected from gold, platinum, palladium, rhodium, nickel, tungsten, molybdenum, chromium, and titanium.

19. The method according to claim 1, wherein after the first metal layer is formed, an arithmetic mean roughness Ra of a surface of the first metal layer is in a range from 100 nm to 2000 nm.

20. The method according to claim 1, wherein before the first metal layer is formed, an arithmetic mean roughness Ra of the surfaces of the first conductor and the second conductor is in a range from 100 nm to 2000 nm.

21. The method according to claim 1, wherein in providing the ceramic substrate, the ceramic substrate is provided having a second arrangement portion recessed from a second planar portion of the second surface, and
the method further comprising:
disposing a third conductive paste containing a third metal powder in the second arrangement portion;
obtaining a third conductor by firing the third conductive paste;
forming a plurality of second recessed portions on a surface of the third conductor disposed in the second arrangement portion by polishing or grinding at least one of the third conductor or the ceramic substrate so that the third conductor and the second surface form the same plane;
disposing a fourth conductive paste containing a fourth metal powder and a fourth organic resin binder in the plurality of second recessed portions;
obtaining a fourth conductor by curing the fourth conductive paste;
polishing or grinding the fourth conductor so that the fourth conductor and the third conductor form the same plane; and
forming a second metal layer on surfaces of the third conductor and the polished or ground fourth conductor.

22. A method for manufacturing a light-emitting device, the method comprising:
providing a sintered compact substrate obtained by the method for manufacturing the sintered compact substrate according to claim 1; and
disposing a light-emitting element comprising an element electrode on the sintered compact substrate,
wherein in disposing the light-emitting element, the element electrode and the first metal layer are electrically connected to each other.

23. A sintered compact substrate comprising:
a ceramic substrate having a first surface and a second surface opposite to the first surface, the ceramic substrate having a first arrangement portion recessed from a first planar portion of the first surface;
a first conductor disposed in the first arrangement portion, the first conductor having a plurality of first recessed portions on a surface of the first conductor;
a second conductor disposed in the plurality of first recessed portions; and
a first metal layer disposed on surfaces of the first conductor and the second conductor,
wherein the first conductor, the second conductor, and the first surface are flush with each other.

24. The sintered compact substrate according to claim 23, wherein the ceramic substrate comprises a through hole connecting the first surface and the second surface, and the first conductor is disposed in the through hole.

25. The sintered compact substrate according to claim 23, wherein an arithmetic mean roughness Ra of surfaces of the first conductor and the second conductor is in a range from 100 nm to 2000 nm.

26. The sintered compact substrate according to claim 23, wherein an arithmetic mean roughness Ra of a surface of the first metal layer is in a range from 100 nm to 2000 nm.

27. The sintered compact substrate according to claim 23, wherein an area of the plurality of first recessed portion is in a range from 25 μm² to 1 mm² in plan view.

28. The sintered compact substrate according to claim 23, wherein a depth of the plurality of first recessed portions is in a range from 2 μm to 50 μm in cross-sectional view.

29. The sintered compact substrate according to claim 23, wherein the second conductor contains a second metal powder and a second organic resin cured product, and the second metal powder and the first metal layer are electrically connected to each other.

30. The sintered compact substrate according to claim 23, wherein the ceramic substrate comprises
a second arrangement portion recessed from a second planar portion of the second surface;
a third conductor disposed in the second arrangement portion, the third conductor having a plurality of second recessed portions on a surface of the third conductor;
a fourth conductor disposed in the plurality of second recessed portions; and
a second metal layer disposed on surfaces of the third conductor and the fourth conductor,
wherein the third conductor, the fourth conductor, and the second surface form the same plane.

31. A light-emitting device comprising:
the sintered compact substrate according to claim 23; and
a light-emitting element disposed on the sintered compact substrate, the light-emitting element having an element electrode,
wherein the element electrode and the first metal layer are electrically connected to each other.
